(19) United States
(12) Patent Application Publication
(10) Pub. No.: US 2026/0245647 A1
(43) Pub. Date: Aug. 20, 2026

(54) STORAGE DEVICE AND OPERATING METHOD OF THE SAME

(71) Applicant: SK hynix Inc., Gyeonggi-do (KR)

(72) Inventors: Sang Ho YUN, Gyeonggi-do (KR); Jang Seob KIM, Gyeonggi-do (KR); Hong Sik YUN, Gyeonggi-do (KR); Jeong Myung LEE, Gyeonggi-do (KR); Hyuk Min KWON, Gyeonggi-do (KR)

(21) Appl. No.: 19/387,633

(22) Filed: Nov. 13, 2025

(30) Foreign Application Priority Data
Feb. 20, 2025 (KR) 10-2025-0022417
Jul. 4, 2025 (KR) 10-2025-0090186

(51) Int. Cl. G11C 29/42; G11C 29/12

(52) U.S. Cl. CPC G11C 29/42; G11C 29/12005

(57) ABSTRACT

A method of operating a storage device includes determining, for a plurality of memory cells, a first mean value and a first variance value of a first threshold voltage distribution and a second mean value and a second variance value of a second threshold voltage distribution, adjacent to each other, determining candidates for a read level based on the first and second mean values and the first and second variance values, performing a first read operation and a first ECC operation based on a first candidate, performing, in response to a fail of the first ECC operation, a second read operation and a second ECC operation based on a second candidate, determining, as the read level, a candidate corresponding to a smaller one of first and second syndrome values indicating numbers of fail bits, and performing a third read operation and a third ECC operation based on the read level.

### CROSS-REFERENCE TO RELATED APPLICATIONS

The present application claims priority under 35 U.S.C. § 119(a) to Korean patent application No. 10-2025-0022417 filed on Feb. 20, 2025 and Korean patent application No. 10-2025-0090186 filed on Jul. 4, 2025, the entire disclosures of which are incorporated herein by reference.

### BACKGROUND

### 1. Technical Field

Embodiments of the present disclosure generally relate to a storage device and an operating method thereof, and more particularly, to a storage device determining a read level and a method of operating the storage device.

### 2. Related Art

A memory device stores data in response to a write request and outputs stored data in response to a read request. For example, a memory device may be classified into volatile memory devices, such as Dynamic Random Access Memory (DRAM), Static Random Access Memory (SRAM), etc., which lose stored data when power is cut off, and volatile memory devices such as flash memory devices, Phase-change Random Access Memory (PRAM), Magnetic Random Access Memory (MRAM), Resistive Random Access Memory (RRAM), etc., which retain stored data even when power is cut off.

A non-volatile memory device may include a plurality of memory cells. When read operations are performed on the plurality of memory cells, threshold voltages of the plurality of memory cells may change due to various factors. A read operation based on a preset read voltage may fail due to these threshold voltage variations. In response to such read fail, a technique capable of determining a new optimal read voltage may be required.

### SUMMARY

Embodiments of the present disclosure provide a storage device determining a read level and a method of operating the storage device.

According to an embodiment of the present disclosure, a method of operating a storage device is provided. The operating method may include determining, for a plurality of memory cells, a first mean value and a first variance value of a first threshold voltage distribution and a second mean value and a second variance value of a second threshold voltage distribution, the first and second threshold voltage distributions being adjacent to each other, determining candidates for a read level based on the first and second mean values and the first and second variance values, performing a first read operation and a first Error Correction Code (ECC) operation on the plurality of memory cells, based on a first candidate among the candidates, performing, in response to a fail of the first ECC operation, a second read operation and a second ECC operation on the plurality of memory cells based on a second candidate among the candidates, determining, as the read level, a candidate corresponding to a smaller syndrome value of first and second syndrome values respectively indicating numbers of fail bits in the first and second ECC operations, and performing a third read operation and a third ECC operation on the plurality of memory cells based on the read level.

According to an embodiment of the present disclosure, a storage device is provided. The storage device may include a memory device including a plurality of memory cells and a peripheral circuit, and a memory controller configured to determine, for the plurality of memory cells, a first mean value and a first variance value of a first threshold voltage distribution and a second mean value and a second variance value of a second threshold voltage distribution, the first and second threshold voltage distributions being adjacent to each other, determine candidates for a read level based on the first and second mean values and the first and second variance values, perform a first read operation and a first Error Correction Code (ECC) operation on the plurality of memory cells based on a first candidate among the candidates, perform, in response to a fail of the first ECC operation, a second read operation and a second ECC operation on the plurality of memory cells based on a second candidate among the candidates, determine, as the read level, a candidate corresponding to a smaller syndrome value of first and second syndrome values respectively indicating numbers of fail bits in the first and second ECC operations, and perform a third read operation and a third ECC operation on the plurality of memory cells based on the read level.

According to an embodiment of the present disclosure, a method of operating a memory controller is provided. The operating method may include determining, for a plurality of memory cells, a first mean value and a first variance value of a first threshold voltage distribution and a second mean value and a second variance value of a second threshold voltage distribution, the first and second threshold voltage distributions being adjacent to each other, determining candidates for a read level based on the first and second mean values and the first and second variance values, performing a first read operation and a first Error Correction Code (ECC) operation on the plurality of memory cells based on a first candidate among the candidates, performing, in response to a fail of the first ECC operation, a second read operation and a second ECC operation on the plurality of memory cells based on a second candidate among the candidates, determining, as the read level, a candidate corresponding to a smaller syndrome value of the first and second syndrome values respectively indicating numbers of fail bits in the first and second ECC operations, and performing a third read operation and a third ECC operation on the plurality of memory cells based on the read level.

### BRIEF DESCRIPTION OF THE DRAWINGS

The above and other aspects and features of embodiments according to the present disclosure will become more apparent by describing, in further detail, aspects of some embodiments thereof with reference to the accompanying drawings, in which:

FIG. 1 is a block diagram illustrating a configuration of a storage device according to an embodiment of the present disclosure;

FIG. 2 is a block diagram illustrating a detailed configuration of a memory device according to an embodiment of the present disclosure;

FIG. 3 is a diagram illustrating adjacent threshold voltage distributions according to some embodiments of the present disclosure;

FIG. 4 is a flowchart illustrating a defense operation of a storage device according to an embodiment of the present disclosure;

FIG. 5 is a flowchart illustrating a method of operating a storage device according to an embodiment of the present disclosure;

FIG. 6A is a diagram illustrating a first candidate among candidates for a read level according to some embodiments of the present disclosure;

FIG. 6B is a diagram illustrating a second candidate among candidates for a read level according to some embodiments of the present disclosure;

FIG. 6C is a diagram illustrating a third candidate among candidates for a read level according to some embodiments of the present disclosure;

FIG. 6D is a diagram illustrating a fourth candidate among candidates for a read level according to some embodiments of the present disclosure;

FIG. 7 is a flowchart illustrating a method of operating a storage device determining a first candidate according to some embodiments of the present disclosure;

FIG. 8A is a diagram illustrating an offset according to some embodiments of the present disclosure;

FIG. 8B is a diagram illustrating an offset according to some embodiments of the present disclosure;

FIG. 8C is a diagram illustrating an offset according to some embodiments of the present disclosure;

FIG. 9 is a block diagram illustrating a configuration of a storage device according to embodiments of the present disclosure; and

FIG. 10 is a is a block diagram illustrating a configuration of an electronic system according to some embodiments of the present disclosure.

### DETAILED DESCRIPTION

Hereinafter, embodiments of the present disclosure will be described in detail with reference to the accompanying drawings so that those skilled in the art can readily practice the invention.

Herein, terms such as “first” and “second” may be used to describe various components, but these components are not limited to these terms. The terms are used to distinguish one component from another component.

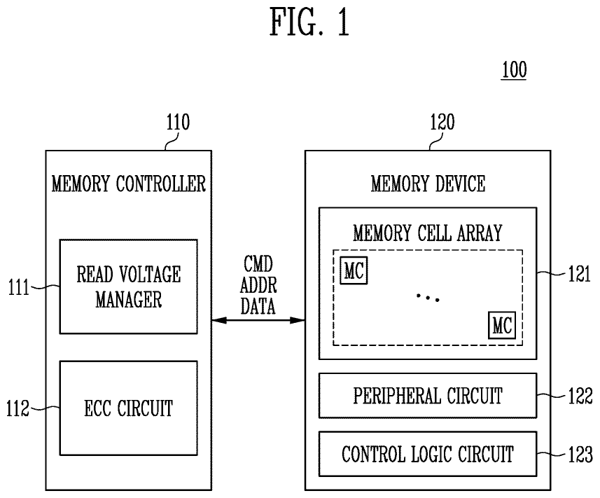

FIG. 1 is a block diagram illustrating a configuration of a storage device 100 according to an embodiment of the present disclosure. The storage device 100 may store data. For example, the storage device 100 may store data under the control of an external host device (not shown). In some embodiments, the storage device 100 may include at least one of a solid-state device (SSD), embedded memory, and removable external memory. When the storage device 100 is an SSD, the storage device 100 may be a device conforming to the Non-Volatile Memory Express (NVMe) standard. When the storage device 100 is embedded memory or removable external memory, the storage device 100 may be a device conforming to the Universal Flash Storage (UFS) or embedded Multi-Media Card (eMMC) standard. The storage device 100 and the external host device (not shown) may generate packets based on the adopted standard protocols and transfer the generated packets to each other.

The storage device 100 may include a memory controller 110 and a memory device 120. The memory controller 110 may control the operation of the storage device 100. For example, the memory controller 110 may control the operation of the storage device 100 according to internal policies or in response to requests from the external host device (not shown). The memory controller 110 may store data DATA in the memory device 120 or read the data DATA stored in the memory device 120 either according to internal policies or in response to requests from the external host device (not shown).

The memory controller 110 may provide a command CMD and an address ADDR to the memory device 120 to control the memory device 120, and may communicate data DATA with the memory device 120. For example, to perform a read operation of data DATA stored in the memory device 120, the memory controller 110 may provide the memory device 120 with the command CMD indicating the read operation and the address ADDR of the data DATA, and may receive the data DATA from the memory device 120.

In some embodiments, the memory controller 110 may determine whether a read operation passes or fails. For example, after the memory controller 110 provides the command CMD and the address ADDR to the memory device 120, the memory controller 110 may determine whether the read operation passes or fails. The memory controller 110 may perform a defense operation (for example, a corrective action) in response to a fail (i.e., a read fail). The defense operation may refer to an operation to eliminate elements within the storage device 100 which cause the read fail.

The elements which may cause the read fail may be diverse. For example, the elements may include various factors such as read disturb, retention loss, and memory cell degradation. These factors may cause variations in an optimal read level applied to a plurality of memory cells MC, and variations in the optimal read level may cause read fail. In other words, each of these issues may cause the optimal read voltage for a memory cell MC to shift, potentially leading to read errors. The memory controller 110 may complete the defense operation by determining a new optimal read level in response to the read fail.

The memory controller 110 may include a read voltage manager 111 and an Error Correction Code (ECC) circuit 112. The read voltage manager 111 may determine a read voltage to be applied to the plurality of memory cells MC during a read operation of the memory controller 110. For example, the read voltage manager 111 may store information regarding the optimal read voltage for the plurality of memory cells MC and may determine the optimal read voltage based on this information. However, due to degradation of the plurality of memory cells MC, the read voltage manager 111 may need to determine a new optimal read voltage.

In some embodiments, the read voltage manager 111 may compute candidates for the read level in response to the read fail and may determine the optimal read level among the candidates. For example, the read voltage manager 111 may compute candidates based on the threshold voltage distributions of the plurality of memory cells MC, determine the candidates, and then determine a read level based on results of read operations and ECC operations performed based on the respective candidates. A more detailed description of the read voltage manager 111 or the memory controller 110 for determining the optimal read level will be provided below.

The ECC circuit 112 may correct fail bits. For example, the ECC circuit 112 may correct fail bits within the data DATA read from the memory device 120. In some embodiments, the ECC circuit 112 may correct the fail bits when the number of fail bits is equal to or less than the number of correctable bits. However, when the number of fail bits exceeds the number of correctable bits, the ECC circuit 112 may determine that a fail has occurred in the read operation.

In some embodiments, the ECC circuit 112 may perform hard decoding operations and soft decoding operations. A soft decoding operation may have superior error correction performance compared to a hard decoding operation, but may require greater overhead and computing performance. The ECC circuit 112 may perform hard decoding operations based on candidates for an optimal read level, and after performing each hard decoding operation, determine a syndrome indicating the number of fail bits. For each candidate read level, the memory controller 110 may determine a syndrome value that provides a measure of how error-free (for example, clean) the data is when read at that read level. In instances in which a determined syndrome indicates a number of errors equal to or less than the correction limit of the ECC circuit 112, the ECC circuit 112 may use the syndrome value to identify the exact location of the error and automatically correct the bit errors. Furthermore, after the optimal read level is determined among the candidates, the ECC circuit 112 may perform a soft decoding operation based on the optimal read level.

When the memory controller 110 completes the defense operation, the number of fail bits within the data DATA read from the memory device 120 may be reduced to a correctable number or less.

The memory device 120 may store data under the control of the memory controller 110. For example, the memory device 120 may store the data DATA or read the stored data DATA and provide the data DATA to the memory controller 110 based on the command CMD and the address ADDR received from the memory controller 110.

The memory device 120 may be a non-volatile memory device such as NAND Flash memory, but the present disclosure is not limited thereto. The memory device 120 may be one of various devices capable of retaining stored data even when power is cut off, such as Phase-change Random Access Memory (PRAM), Magnetic Random Access Memory (MRAM), Resistive Random Access Memory (RRAM), or Ferroelectric Random Access Memory (FRAM).

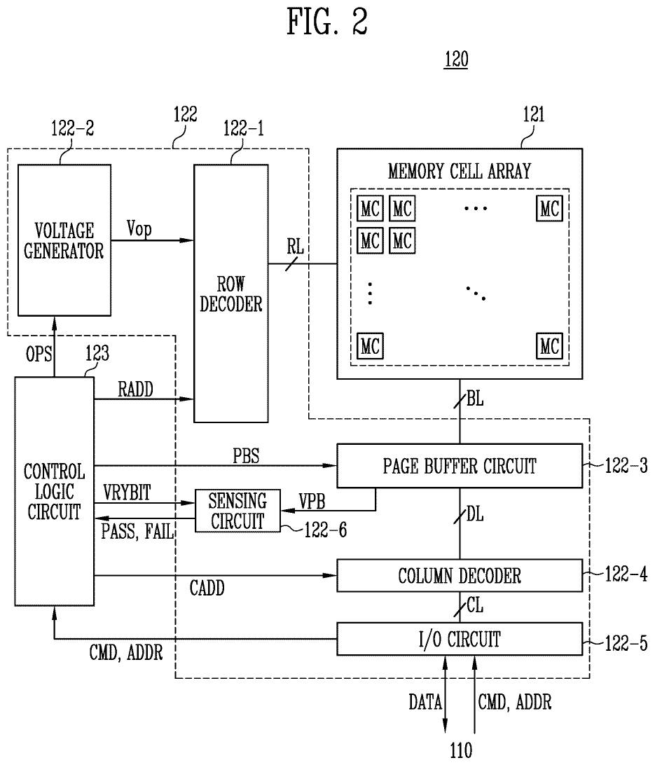

The memory device 120 may include a memory cell array 121, a peripheral circuit 122, and a control logic circuit 123. The memory cell array 121 may include the plurality of memory cells MC. A more detailed description of the memory cell array 121, the peripheral circuit 122, and the control logic circuit 123 will be provided below with reference to FIG. 2.

FIG. 2 is a block diagram illustrating a detailed configuration of the memory device 120 according to an embodiment of the present disclosure. Referring to FIG. 2, the memory device 120 may include the memory cell array 121, the peripheral circuit 122, and the control logic circuit 123.

The memory cell array 121 may include a plurality of memory blocks. Each of the plurality of memory blocks may include a plurality of memory cells MC and have a two-dimensional (or planar) structure arranged parallel to a substrate or a three-dimensional structure stacked vertically on the substrate.

The peripheral circuit 122 may include a row decoder 122-1, a voltage generator 122-2, a page buffer circuit 122-3, a column decoder 122-4, an input/output (I/O) circuit 122-5, and a sensing circuit 122-6.

The row decoder 122-1 may select some of the plurality of memory cells MC within the memory cell array 121 based on a row address RADD, and may transfer operation voltages Vop to selected memory cells.

The row decoder 122-1 may be coupled to the memory cell array 121 via row lines RL. The row lines RL may include first and second select lines, and a plurality of word lines arranged between the first and second select lines. In addition, the row lines RL may include dummy lines arranged between a first select line and the plurality of word lines, and between a second select line and the plurality of word lines. The first select line may be a source select line, and the second select line may be a drain select line.

The row decoder 122-1 may select one of the row lines RL based on the row address RADD, and may transfer the operation voltages Vop to a memory block or a memory cell coupled to the selected row line RL. The operation voltages Vop may include a program voltage, a verify voltage, a read voltage, a pass voltage, and an erase voltage.

The voltage generator 122-2 may generate and output the operation voltages Vop. For example, the voltage generator 122-2 may generate and output the operation voltages Vop required for various operations in response to an operation signal OPS received from the control logic circuit 123. The voltage generator 122-2 may output the generated operation voltages Vop to the plurality of memory cells MC within the memory cell array 121 via the read decoder 122-1.

In some embodiments, the voltage generator 122-2 may generate the operation voltages Vop and output the operation voltages Vop to the plurality of memory cells MC via the row decoder 122-1 to apply the read level (or candidates) determined by the memory controller 110 to the plurality of memory cells MC. For example, the control logic circuit 123 may generate the operation signal OPS based on the command CMD received from the memory controller 110 to perform a read operation based on the read level or the candidates for the read level, and may provide the operation signal OPS to the voltage generator 122-2. Subsequently, the voltage generator 122-2 may generate the operation voltages Vop based on the operation signal OPS to apply the read level or candidates for the read level to the plurality of memory cells MC, and may output the operation voltages Vop to the plurality of memory cells MC via the row decoder 122-1.

The page buffer circuit 122-3 may be coupled to the memory cell array 121 via bit lines BL. The page buffer circuit 122-3 may include a plurality of page buffers coupled to each bit line BL. The page buffer circuit 122-3 may be a temporary storage area in a flash memory device that holds data being written to or read from the memory cells MC. The page buffer circuit 122-3 may act as a buffer to coordinate the flow of data between the memory cell array 121 and other components of the memory device 120 including the memory controller 110. The page buffer circuit 122-3 may operate in response to page buffer control signals PBS and temporarily store data during a program operation or a read operation.

The page buffer circuit 122-3 may sense the bit lines BL during a read operation or a verify operation. For example, to perform a read or verify operation on the plurality of memory cells MC coupled via the bit lines BL, the page buffer circuit 122-3 may sense voltages on the bit lines BL and compare the sensed voltages with the threshold voltages of the plurality of memory cells MC.

The column decoder 122-4 may transfer data between the page buffer circuit 122-3 and the I/O circuit 122-5 based on a column address CADD. For example, the column decoder 122-4 may communicate the data DATA with the page buffer circuit 122-3 via data lines DL, or communicate the data DATA with the I/O circuit 122-5 via column lines CL.

The I/O circuit 122-5 may communicate with the memory controller 110 of FIG. 1. For example, the I/O circuit 122-5 may receive the command CMD and the address ADDR from the memory controller 110 or an external device, and may receive and transmit the data DATA. The I/O circuit 122-5 may provide the received command CMD and address ADDR to the control logic circuit 123, and may provide the data DATA to the column decoder 122-4 via the column lines CL. The I/O circuit 122-5 may provide the data DATA received from the column decoder 122-4 to the memory controller 110 or the external device.

The sensing circuit 122-6 may generate a reference current in response to an allowable bit VRYBIT during a read operation or a verify operation, and may output a pass signal PASS or a fail signal FAIL by comparing a sensing voltage VPB received from the page buffer circuit 122-3 and a reference voltage generated by the reference current.

The control logic circuit 123 may control the peripheral circuit 122. For example, the control logic circuit 123 may generate and output various signals for controlling the peripheral circuit 122. In some embodiments, the control logic circuit 123 may output the operation signal OPS, the row address RADD, the allowable bit VRYBIT, the page buffer control signals PBS, and the column address CADD in response to the command CMD and the address ADDR.

The control logic circuit 123 may include software which performs an algorithm in response to the command CMD, and hardware or modules configured to output various signals based on the address ADDR and the algorithm. For example, the control logic circuit 123 may adjust voltage levels of various signals included in the page buffer control signals PBS during a read operation or a verify operation.

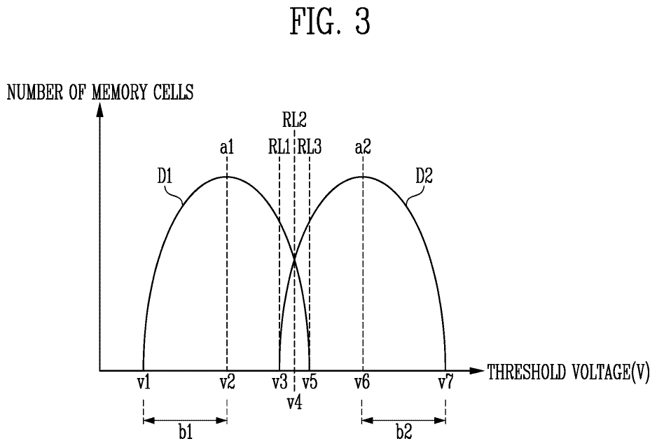

FIG. 3 is a diagram illustrating adjacent threshold voltage distributions according to some embodiments of the present disclosure. Referring to FIGS. 1 to 3, the horizontal axis represents threshold voltages of the plurality of memory cells MC, and the vertical axis represents the number of memory cells having threshold voltages.

The plurality of memory cells MC may form threshold voltage distributions (e.g., first and second threshold voltage distributions D1 and D2) according to the stored data. For example, when the plurality of memory cells MC store data including one or more bits, the plurality of memory cells MC may have corresponding threshold voltages among the threshold voltages according to the stored data. A threshold voltage distribution indicates that not all memory cells MC storing the same digital value have the exact same threshold voltage. Instead, the threshold voltages of the memory cells MC may cluster around a specific average value, forming a distribution (which may be approximated as a Gaussian distribution).

For better understanding, two threshold voltage distributions (e.g., the first and second threshold voltage distributions D1 and D2) are shown; however, the present disclosure is not limited thereto. The plurality of memory cells MC may have at least two threshold voltage distributions. This use of multiple threshold voltages enables multi-level cell (MLC) technology, which increases storage density by storing more than one bit per cell.

The plurality of memory cells MC may be turned on or turned off in response to a read level, based on threshold voltages thereof. For example, each of the plurality of memory cells MC may be turned on when a read level higher than a corresponding threshold voltage is applied, and may be turned off when a read level lower than the corresponding threshold voltage is applied. The peripheral circuit 122 may sense whether the plurality of memory cells MC are turned on or off via the bit lines BL to read data.

The threshold voltage distribution may represent the distribution of the plurality of memory cells MC each having a corresponding threshold voltage. For example, the first threshold voltage distribution D1 may represent the distribution of some memory cells having threshold voltages between a first voltage v1 and a fifth voltage v5 (among the plurality of memory cells MC). In addition, the second threshold voltage distribution D2 may represent the distribution of other memory cells having threshold voltages between a third voltage v3 and a seventh voltage v7 (among the plurality of memory cells MC). The first and second threshold voltage distributions D1 and D2 may be adjacent to each other.

In embodiments, adjacent threshold voltage distributions may partially overlap each other. For example, portions of the first and second threshold voltage distributions D1 and D2 (e.g., portions between the third voltage v3 and the fifth voltage v5) may overlap each other. The overlapping portions of adjacent threshold voltage distributions may cause read fail (for example, because the memory controller 110 may not be able to reliably distinguish between the two states in the overlapping region).

Read levels (e.g., first to third read levels RL1 to RL3) are applied to the plurality of memory cells MC to distinguish data between adjacent threshold voltage distributions (e.g., the first and second threshold voltage distributions D1 and D2). However, when a read level is applied to overlapping portions (e.g., memory cells having threshold voltages between the third voltage v3 and the fifth voltage v5) of adjacent threshold voltage distributions (e.g., the first and second threshold voltage distributions D1 and D2), a fail bit may occur.

The ECC circuit 112 in FIG. 1 may correct fail bits which occur during read operations. However, when the number of fail bits exceeds a correctable number, the ECC circuit 112 may not be able to correct the fail bits (i.e., the ECC operation fails), and the memory controller 110 may determine that a read fail has occurred.

Therefore, the memory controller 110 may determine read levels (e.g., the first to third read levels RL1 to RL3) to distinguish data between adjacent threshold voltage distributions (e.g., the first and second threshold voltage distributions D1 and D2) such that the number of fail bits may not exceed the correctable number (and the number of fail bits is minimized).

In some embodiments, when the first read level RL1 is applied to the plurality of memory cells MC, data corresponding to the second threshold voltage distribution D2 does not have a fail bit, but data corresponding to memory cells having threshold voltages between the third voltage v3 and the fifth voltage v5 in the first threshold voltage distribution D1 may have fail bits.

In some embodiments, when the second read level RL2 is applied to the plurality of memory cells MC, data corresponding to memory cells having threshold voltages between a fourth voltage v4 and the fifth voltage v5 in the data corresponding to the first threshold voltage distribution D1, and data corresponding to memory cells having threshold voltages between the third voltage v3 and the fourth voltage v4 in the data corresponding to the second threshold voltage distribution D2 may have fail bits.

In some embodiments, when the third read level RL3 is applied to the plurality of memory cells MC, data corresponding to the first threshold voltage distribution D1 does not have fail bits, but data corresponding to memory cells having threshold voltages between the third voltage v3 and the fifth voltage v5 among data corresponding to the second threshold voltage distribution D2 may have fail bits.

As described above, when adjacent threshold voltage distributions (e.g., the first and second threshold voltage distributions D1 and D2) partially overlap, the data corresponding to the overlapping portion may have fail bits. The memory controller 110 may determine one of the read levels (or the candidates for a read level) (e.g., the first to third read levels RL1 to RL3) as an optimal read level to minimize the number of fail bits.

The memory controller 110 in FIG. 1 may Gaussian-model threshold voltage distributions (e.g., the first and second threshold voltage distributions D1 and D2). For example, the first and second threshold voltage distributions D1 and D2 shown in FIG. 2 may be Gaussian distributions Gaussian-modelled by the memory controller 110.

However, for better understanding, the Gaussian model is described as an example, but the present disclosure is not limited thereto. The Gaussian-modelled threshold voltage distribution (or the Gaussian distribution) may be expressed as shown in Equation 1 below.

$$GD = \frac{1}{2 \sqrt{π} b} {e}^{- \frac{{( vth - a )}^{2}}{2 {b}^{2}}} \qquad [ Equation 1 ]$$

In Equation 1, GD is the Gaussian-modelled threshold voltage distribution (or the Gaussian distribution), a is the mean value, b is the variance value, and vth is the threshold voltage.

The memory controller 110 may determine the mean values (e.g., first and second mean values a1 and a2), and the variance values (e.g., first and second variance values b1 and b2) of the threshold voltage distributions (e.g., the first and second threshold voltage distributions D1 and D2). For example, the memory controller 110 may Gaussian-model the first and second threshold voltage distributions D1 and D2, and may determine the first and second mean values a1 and a2 and the first and second variance values b1 and b2 based on the Gaussian-modelled first and second threshold voltage distributions D1 and D2.

The memory controller 110 may determine an optimal read level based on the Gaussian-modelled threshold voltage distributions. A more detailed description thereof will be provided below.

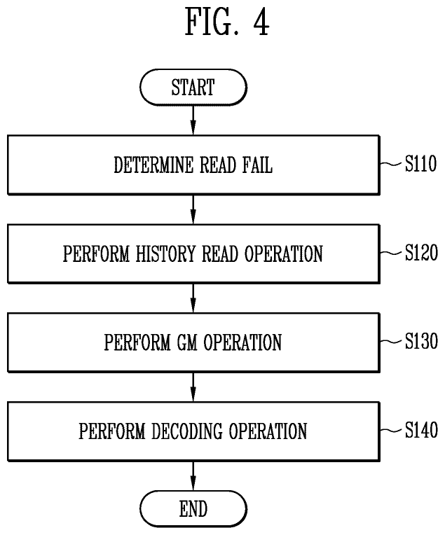

FIG. 4 is a flowchart illustrating a defense operation of the storage device 100 according to an embodiment of the present disclosure. Referring to FIG. 4, the storage device 100 of FIG. 1 may perform a defense operation in response to a read fail.

In operation S110, the storage device 100 or the memory controller 110 may determine that a read fail has occurred. For example, the memory controller 110 may determine that a read fail has occurred in response to determining that the number of fail bits within the data DATA received from the memory device 120 exceeds a correctable number. For example, the memory controller 110 may be able to correct errors up to the correctable number, which may form a limit, often a single-bit error per data word. These errors within the limit may be logged (and corrected) but do not cause a read fail. When the correctable number is exceeded, the memory controller 110 may determine occurrence of the read fail.

In operation S120, the storage device 100 or the memory controller 110 may perform a history read operation. For example, the storage device 100 or the memory controller 110 may perform a read operation based on a read level determined by a previous defense operation or a predetermined read level in response to the read fail.

In operation S130, the storage device 100 or the memory controller 110 may perform a Gaussian modelling (GM) operation. For example, the memory controller 110 may perform Gaussian modelling of the threshold voltage distributions into Gaussian distributions and may perform a read operation based on a read level between adjacent Gaussian distributions in response to a read fail which has occurred after performing the read operation in the operation S120.

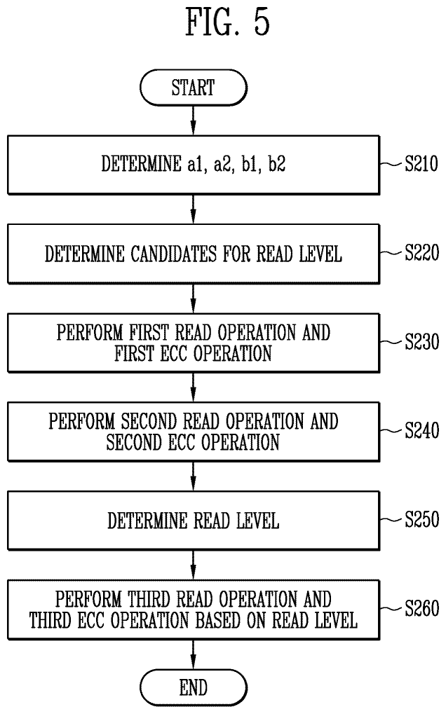

In operation S140, the storage device 100 or the memory controller 110 may perform a decoding operation. For example, the memory controller 110 may determine an optimal read level by computing candidates for the optimal read level and performing hard decoding and soft decoding operations in response to the read fail occurring after performing the read operation in the operation S130. The memory controller 110 may compute candidates for the optimal read level and determine a candidate with the fewest read fail bits as the optimal read level. A more detailed description thereof will be provided below with reference to FIG. 5.

FIG. 5 is a flowchart illustrating a method of operating the storage device 100 according to an embodiment of the present disclosure. Referring to FIG. 5, the storage device 100 of FIG. 1 may determine an optimal read level and perform a read operation and an ECC operation (or a decoding operation) based on the determined read level.

For better understanding, a method of operating the storage device determining the optimal read level between two adjacent threshold voltage distributions is described below. However, the present disclosure is not limited thereto (and may, for example, be applied to multiple adjacent threshold voltage distributions). The storage device 100 may determine optimal read levels for at least two adjacent threshold voltage distributions.

In operation S210, the storage device 100 or the memory controller 110 may determine the first and second mean values a1 and a2 and the first and second variance values b1 and b2. For example, the memory controller 110 may determine the first and second mean values a1 and a2 and the first and second variance values b1 and b2 of the first and second threshold voltage distributions D1 and D2 (or the first and second Gaussian-modelled threshold voltage distributions or the first and second Gaussian distributions) as shown in FIG. 3.

In operation S220, the storage device 100 or the memory controller 110 may determine candidates for a read level. For example, the memory controller 110 may determine candidates for a read level to determine an optimal read level for distinguishing the first and second threshold voltage distributions D1 and D2. The optimal read level may refer to a read level which results in the fewest number of fail bits when a read operation is performed on the memory cells of the first and second threshold voltage distributions D1 and D2.

In some embodiments, the memory controller 110 may compute values of candidates for a read level and determine the candidates based on the computed values. For example, the memory controller 110 may compute the values of the candidates based on the first and second mean values a1 and a2 and the first and second variance values b1 and b2, and may determine the computed values or discretized (or quantized) values of the computed values as the candidates.

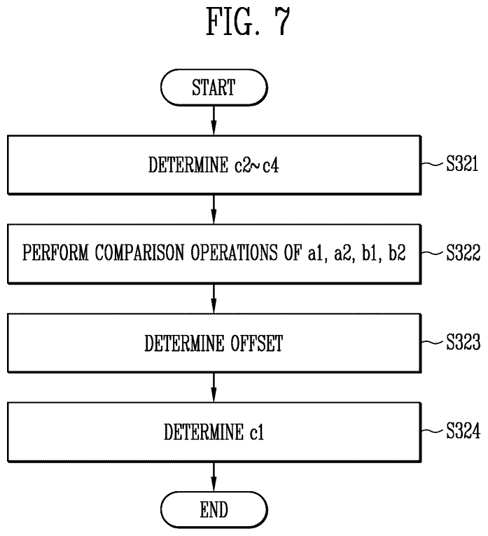

In some embodiments, the memory controller 110 may determine some candidates based on other candidates. For example, the computational operations for some candidates may be complex, requiring significant computing performance and overhead. Therefore, the memory controller 110 may determine some candidates based on other candidates whose computational operations are not (for example, as comparatively) complex. For example, the memory controller 110 may determine some candidates based on the addition operation of the determined other candidates and an offset. A more detailed description thereof will be provided below with reference to FIG. 7.

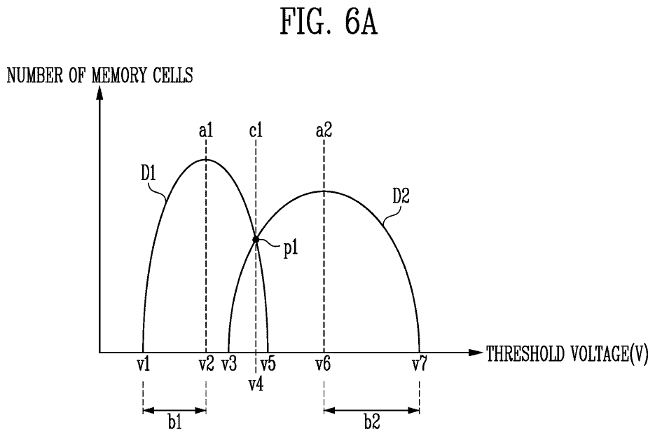

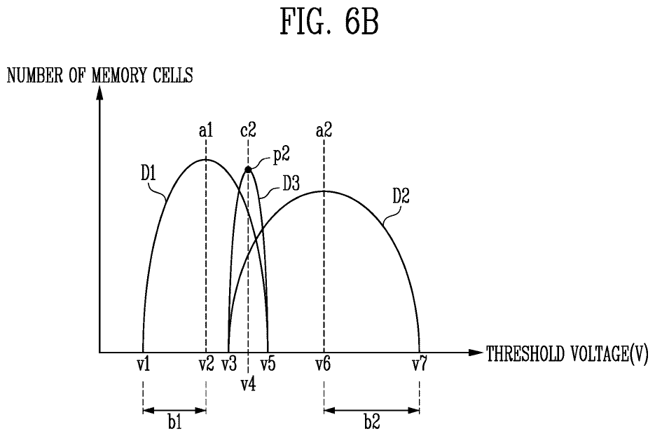

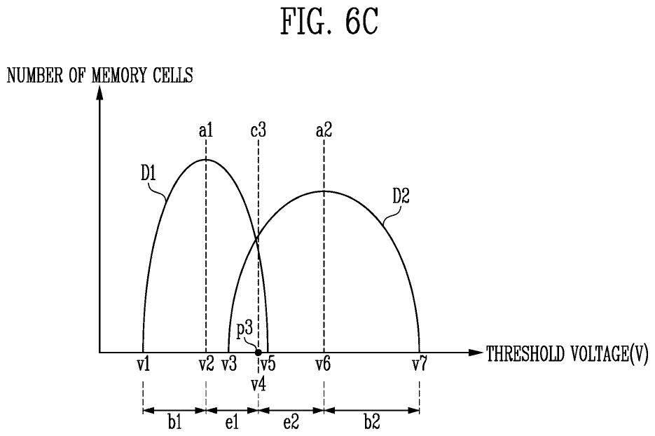

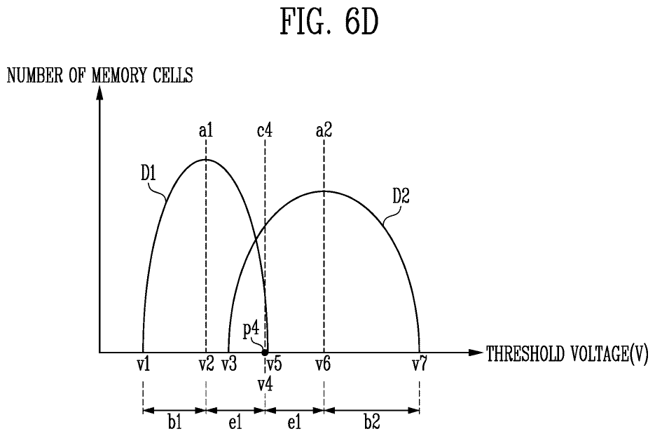

The memory controller 110 may determine at least two candidates. The memory controller 110 may determine the intersection point of the first and second threshold voltage distributions D1 and D2 (or first and second Gaussian distributions) as a first candidate. A more detailed description of the first candidate will be provided below with reference to FIG. 6A.

In some embodiments, the memory controller 110 may determine a mean value of a third distribution, which is the result of a multiplication operation between the first and second threshold voltage distributions D1 and D2 (or the Gaussian-modelled first and second Gaussian distributions) as a second candidate. A more detailed description of the second candidate will be provided below with reference to FIG. 6B.

In some embodiments, the memory controller 110 may determine an internal division point of the first and second mean values a1 and a2, weighted by the first and second variance values b1 and b2 of the first and second threshold voltage distributions D1 and D2 (or the Gaussian-modelled first and second Gaussian distributions), as a third candidate. A more detailed description of the third candidate will be provided below with reference to FIG. 6C.

In some embodiments, the memory controller 110 may determine an average of the first and second mean values a1 and a2 of the first and second threshold voltage distributions D1 and D2 (or the Gaussian-modelled first and second Gaussian distributions) as a fourth candidate. A more detailed description of the fourth candidate will be provided below with reference to FIG. 6D.

For better understanding, the four candidates including the first to fourth candidates have been described; however, the present disclosure is not limited thereto. The memory controller 110 may further determine additional candidates in addition to (or substitution for some of) the above-described four candidates.

In operation S230, the storage device 100 or the memory controller 110 may perform a first read operation and a first ECC operation on the plurality of memory cells MC of FIG. 1 based on the first candidate among the candidates. For example, the memory controller 110 may perform the first read operation on the plurality of memory cells MC (e.g., memory cells of the first and second threshold voltage distributions D1 and D2) with the first candidate as a read level, and then perform the first ECC operation on the read data.

In some embodiments, the memory controller 110 performs a first ECC operation on the read data as a result of the first read operation performed based on the first candidate, and determines whether a read fail has occurred based on the number of fail bits within the read data. In response to determining that the number of fail bits does not exceed a correctable number, the memory controller 110 may determine the read operation as a pass or the completion of a defense operation and may determine the first candidate as an optimal read level.

In operation S240, the storage device 100 or the memory controller 110 may perform a second read operation and a second ECC operation based on the second candidate. For example, in response to a fail of the first ECC operation, the memory controller 110 may perform a second read operation of the memory cells MC with the second candidate as the read level, and then perform a second ECC operation on the read data. In other words, the memory controller 110 may perform the second read operation and the second ECC operation based on the second candidate in response to determining that the number of fail bits within the read data based on the first candidate exceeds the correctable number.

For ease of understanding, it is described that the memory controller 110 performs the first and second read operations and the first and second ECC operations based on the first and second candidates, respectively; however, the present disclosure is not limited thereto. The memory controller 110 may further perform read operations and ECC operations based not only on the first to fourth candidates but also on other candidates. Furthermore, the memory controller 110 may perform the first and second read operations and the first and second ECC operations based not only on the first candidate and second candidate described in the operations S230 and S240, but also on other candidates.

In some embodiments, the memory controller 110 may perform a comparison operation between the first and second candidates, and based on a result of the comparison operation, omit the second read operation and the second ECC operation, or determine the first candidate as the optimal read level. For example, when the first and second candidates are identical or similar (the difference therebetween being less than or equal to an arbitrary (and/or preterminal) number), the memory controller 110 may perform the first read operation and the first ECC operation based on the first candidate, then determine the first candidate as the optimal read level without performing the second read operation and the second ECC operation based on the second candidate. However, when there are three or more candidates, the memory controller 110 may perform the second read operation and the second ECC operation based on the third candidate, and then determine one of the first candidate and the third candidate as the optimal read level.

In operation S250, the storage device 100 or the memory controller 110 may determine one of the candidates (e.g., the first and second candidates) as the read level. For example, the memory controller 110 may determine first and second syndrome values, each indicating the number of fail bits, after performing the first and second ECC operations in the operations S230 and S240, respectively. The memory controller 110 may determine a candidate (e.g., first and second candidates), corresponding to the smaller value of the first and second syndrome values as a read level. In other words, the memory controller 110 may determine a candidate which minimizes the number of fail bits as the optimal read level.

In some embodiments, the memory controller 110 may perform at least two read operations and ECC operations based on at least two candidates (e.g., first to fourth candidates). The memory controller 110 may determine at least two syndrome values (e.g., first to fourth syndrome values). The memory controller 110 may determine one of the candidates (e.g., the first to fourth candidates) corresponding to the smallest syndrome among the at least two syndrome values (e.g., the first to fourth syndrome values) as the optimal read level.

In operation S260, the storage device 100 or the memory controller 110 may perform a third read operation and a third ECC operation based on the read level. For example, the memory controller 110 may perform a third read operation and a third ECC operation on the plurality of memory cells MC based on the read level determined in the operation S250.

In some embodiments, the first and second ECC operations performed in the operations S230 and S240 are hard decoding operations, but the third ECC operation performed in the operation S260 may be a soft decoding operation. Each hard decoding operation may require less overhead than soft decoding. Therefore, in the operations S230 and S240, the memory controller 110 performs hard decoding operations based on a plurality of candidates (e.g., first and second candidates) to determine an optimal read level with the smallest number of fail bits (or the smallest syndrome value) and performs a soft decoding operation based on the optimal read level. That is, by performing the hard decoding operations to determine the optimal read level, the memory controller 110 may reduce the overall overhead of the defense operation and consequently improve the performance of the storage device 100.

In accordance with some embodiments, performing the second read operation and the second ECC operation may further comprise performing a fourth read operation and a fourth ECC operation on the plurality of memory cells MC, based on the third candidate, in response to a fail of the second ECC operation. The process may further include performing a fifth read operation and a fifth ECC operation on the plurality of memory cells MC, based on the fourth candidate, in response to a fail of the fourth ECC operation. In this instance, determining the candidate corresponding to the smaller syndrome value of the first and second syndrome values as the read level may comprise determining a candidate corresponding to a smallest syndrome value among the first and second syndrome values indicating the numbers of fail bits in the first and second ECC operations and third and fourth syndrome values indicating numbers of fail bits in the fourth and fifth ECC operations as the read level.

FIG. 6A is a diagram illustrating a first candidate among the candidates for the read level according to some embodiments of the present disclosure. Referring to FIGS. 1 and 6A, the horizontal axis represents the threshold voltages of the plurality of memory cells MC, and the vertical axis represents the number of memory cells.

A first candidate c1 may be the intersection point of the first and second threshold voltage distributions D1 and D2, which are adjacent to each other and partially overlap. In some embodiments, the first and second threshold voltage distributions D1 and D2 may be Gaussian-modelled Gaussian distributions (e.g., referred to respectively as the first and second Gaussian distributions).

The first threshold voltage distribution D1 includes memory cells having threshold voltages between the first voltage v1 and the fifth voltage v5, and the first mean value a1 of the first threshold voltage distribution D1 may be a second voltage v2. Furthermore, the second threshold voltage distribution D2 includes memory cells having threshold voltages between the third voltage v3 and the seventh voltage v7, and the second mean value a2 of the second threshold voltage distribution D2 may be a sixth voltage v6. The first and second variance values b1 and b2 may correspond respectively to the differences between the threshold voltages at the edges of the first and second threshold voltage distributions D1 and D2 and the first and second mean values a1 and a2. However, this is provided as an example and the present disclosure is not limited thereto.

The memory controller 110 may determine the first candidate c1 by calculating the intersection point of the first and second threshold voltage distributions D1 and D2 (e.g., using Gaussian modeling). For example, the memory controller 110 may determine the first candidate c1 by calculating a value corresponding to a threshold voltage at a first point p1 which is the intersection point of the first and second threshold voltage distributions D1 and D2. The memory controller 110 may determine the first candidate c1 based on Equation to 2 described below.

$$c 1 = \frac{\begin{matrix}( a 2 \cdot b {1}^{2} - a 1 \cdot {b}^{2} ) - b 1 \cdot b 2 \cdot \\ \sqrt{{( a 1 - a 2 )}^{2} + 2 \cdot ( b {1}^{2} - b {2}^{2} ) \cdot log \frac{b 1}{b 2}}\end{matrix}}{b {1}^{2} - b {2}^{2}} \qquad [ Equation 2 ]$$

In Equation 2, c1 is the first candidate, a1 is the first mean value of the first threshold voltage distribution (or the first Gaussian distribution) D1, a2 is the second mean value of the second threshold voltage distribution (or the second Gaussian distribution) D2, b1 is the first variance value of the first threshold voltage distribution (or the first Gaussian distribution) D1, and b2 is the second variance value of the second threshold voltage distribution (or the second Gaussian distribution) D2.

According to Equation 2, the memory controller 110 may compute the first candidate c1 based on mean values (e.g., the first and second mean values a1 and a2) and variance values (e.g., the first and second variance values b1 and b2) of the adjacent first and second threshold voltage distributions D1 and D2. The memory controller 110 may determine additional candidates as described herein below with respect to FIG. 6B, FIG. 6C, and FIG. 6D.

FIG. 6B is a diagram illustrating the second candidate among the candidates for the read level according to some embodiments of the present disclosure. Referring to FIGS. 1 and 6B, the horizontal axis represents threshold voltages of the plurality of memory cells MC, and the vertical axis represents the number of memory cells.

The first and second threshold voltage distributions D1 and D2 in FIG. 6B are similar to the first and second threshold voltage distributions D1 and D2 in FIG. 6A. Therefore, redundant descriptions will be omitted below.

The memory controller 110 may determine a mean value of a third distribution D3, which is the result of the multiplication operation of the (e.g., Gaussian-modelled) first and second threshold voltage distributions D1 and D2, as a second candidate c2. For example, the third distribution D3 is the result of the multiplication operation of the Gaussian-modelled first and second threshold voltage distributions D1 and D2, and the third distribution D3 may exist between the third voltage v3 and the fifth voltage v5 (i.e., between the first and second threshold voltage distributions D1 and D2). The memory controller 110 may determine the second candidate c2 based on Equation 3 as follows:

$$c 2 = \frac{a 2 \cdot b {1}^{2} + a 1 \cdot b {2}^{2}}{b {1}^{2} + b {2}^{2}} \qquad [ Equation 3 ]$$

In Equation 3, c2 is the second candidate, a1 is the first variance value of the first threshold voltage distribution (or the first Gaussian distribution) D1, a2 is the second variance value of the second threshold voltage distribution (or the second Gaussian distribution) D2, b1 is the first variance value of the first threshold voltage distribution (or the first Gaussian distribution) D1, and b2 is the second variance value of the second threshold voltage distribution (or the second Gaussian distribution) D2.

According to Equation 3, the memory controller 110 may calculate the second candidate c2 based on mean values (e.g., the first and second mean values a1 and a2) and variance values (e.g., the first and second variance values b1 and b2) of the adjacent first and second threshold voltage distributions D1 and D2. The memory controller 110 may determine additional candidates as described herein below with respect to FIG. 6C and FIG. 6D.

FIG. 6C is a diagram illustrating the third candidate among the candidates for the read level according to some embodiments of the present disclosure. Referring to FIGS. 1 and 6C, the horizontal axis represents the threshold voltages of the plurality of memory cells MC, and the vertical axis represents the number of memory cells.

The first and second threshold voltage distributions D1 and D2 in FIG. 6C are similar to the first and second threshold voltage distributions D1 and D2 in FIG. 6A. Therefore, redundant descriptions will be omitted below.

The memory controller 110 may determine an internal division point of the first and second mean values a1 and a2 having the first and second variance values b1 and b2 of the (e.g., Gaussian-modelled) first and second threshold voltage distributions D1 and D2 as weights (e.g., weights proportional to first and second lengths e1 and e2) as a third candidate c3. For example, the internal division point may correspond to the threshold voltage of a third point p3. The memory controller 110 may determine the third candidate c3 based on Equation 4 as follows:

$$c 3 = \frac{a 1 \cdot b 2 + a 2 \cdot b 1}{b 1 + b 2} \qquad [ Equation 4 ]$$

In Equation 4, c3 is the third candidate, a1 is the first mean value of the first threshold voltage distribution (or the first Gaussian distribution) D1, a2 is the second mean value of the second threshold voltage distribution (or the second Gaussian distribution) D2, b1 is the first variance value of the first threshold voltage distribution (or the first Gaussian distribution) D1, and b2 is the second variance value of the second threshold voltage distribution (or the second Gaussian distribution) D2.

According to Equation 4, the memory controller 110 may compute a third candidate c3 based on mean values (e.g., the first and second mean values a1 and a2) and variance values (e.g., the first and second variance values b1 and b2) of the adjacent first and second threshold voltage distributions D1 and D2. The memory controller 110 may determine additional candidates as described herein below with respect to FIG. 6D.

FIG. 6D is a diagram illustrating the fourth candidate among the candidates for the read level according to some embodiments of the present disclosure. Referring to FIGS. 1 and 6D, the horizontal axis represents the threshold voltages of the plurality of memory cells MC, and the vertical axis represents the number of memory cells.

The first and second threshold voltage distributions D1 and D2 in FIG. 6D are similar to the first and second threshold voltage distributions D1 and D2 in FIG. 6A. Therefore, redundant descriptions will be omitted below.

The memory controller 110 may determine an internal division point of the first and second mean values a1 and a2 having the first and second variance values b1 and b2 of the (e.g., Gaussian-modelled) first and second threshold voltage distributions D1 and D2 as weights (e.g., weights proportional to first and second lengths e1 and e2) as a fourth candidate c4. For example, the fourth candidate c4 may correspond to the threshold voltage of the fourth point p4 positioned at the same length (e.g., the first length e1) from the first and second mean values a1 and a2. The memory controller 110 may determine the fourth candidate c4 based on Equation 5 as follows:

$$c 4 = \frac{a 2 + a 1}{2} \qquad [ Equation 5 ]$$

In Equation 5, c4 is the fourth candidate, a1 is the first mean value of the first threshold voltage distribution (or the first Gaussian distribution D1), and a2 is the second mean value of the second threshold voltage distribution (or the second Gaussian distribution D2).

According to Equation 5, the memory controller 110 may compute the fourth candidate c4 based on mean values of the first and second threshold voltage distributions D1 and D2 (e.g., the first and second mean values a1 and a2). Although particular processes are described for determining the first to fourth candidates c1 to c4, the memory controller 110 may apply additional computations consistent with the present disclosure to identify candidates.

FIG. 7 is a flowchart illustrating a method of operating a storage device determining a first candidate according to some embodiments of the present disclosure. Referring to FIGS. 1, 6A, and 7, the memory controller 110 may determine the first candidate c1.

In some embodiments, the memory controller 110 may compute the first candidate c1 according to the aforementioned Equation 2, but the computational operation of the first candidate may require greater overhead or computing performance than the computational operations of the second to fourth candidates. Therefore, the memory controller 110 may determine the first candidate c1 by performing the computational operation for one of the other candidates (e.g., the second to fourth candidates c2 to c4) and the offset instead of performing the computational operation for the first candidate c1.

The operation S220 (i.e., determine candidates for read level) in FIG. 5 may include operation S321 to S324 in FIG. 7.

In operation S321, the storage device 100 or the memory controller 110 may determine the second to fourth candidates c2 to c4. For example, the memory controller 110 may compute the second to fourth candidates c2 to c4 based on the mean values and the variance values of the adjacent threshold voltage distributions to determine the second to fourth candidates c2 to c4.

In operation S322, the storage device 100 or the memory controller 110 may perform comparison operations on the first and second mean values a1 and a2 and the first and second variance values b1 and b2 of each adjacent threshold voltage distribution. For example, the memory controller 110 may compute the difference value between the first and second mean values a1 and a2, and compute a ratio (or a proportional value) of the first and second variance values b1 and b2.

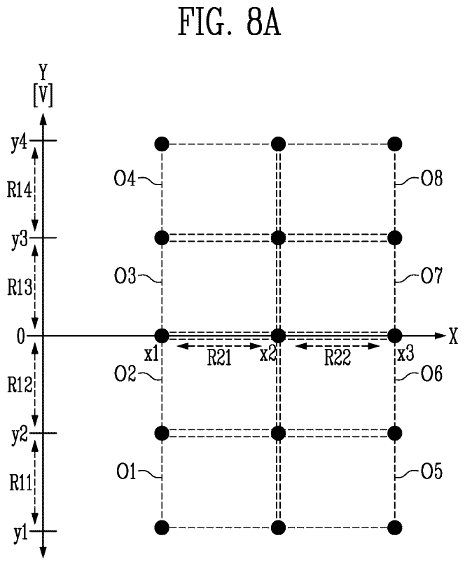

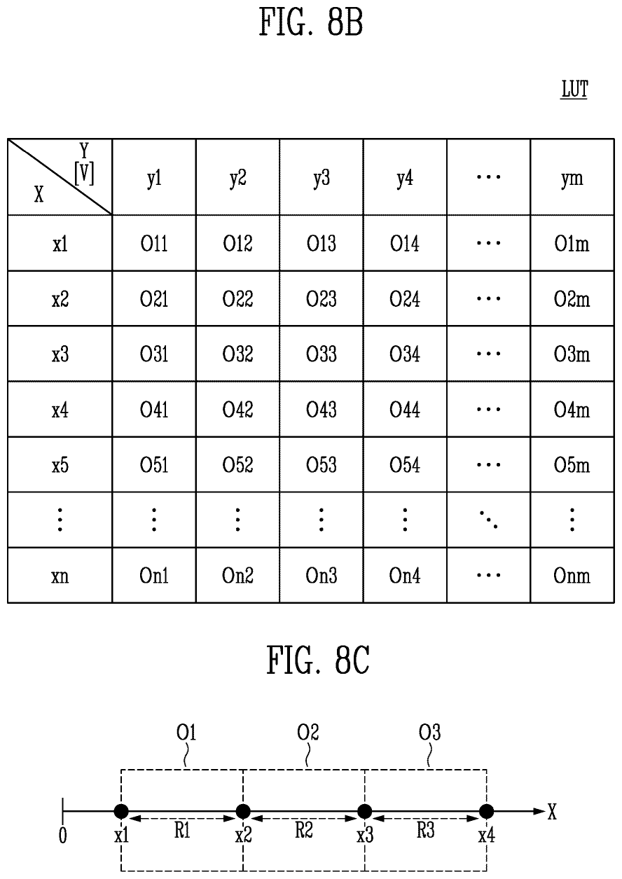

In operation S323, the storage device 100 or the memory controller 110 may determine an offset based on the results of the comparison operations. For example, the memory controller 110 may determine an offset based on the results of the comparison operations of the first and second mean values a1 and a2 and the first and second variance values b1 and b2 to determine the first candidate c1. A more detailed description of determining the offset will be provided below with reference to FIGS. 8A to 8C.

In operation S324, the storage device 100 or the memory controller 110 may determine the first candidate c1. For example, the memory controller 110 may determine the first candidate c1 by performing an addition operation between the offset and one of the second to fourth candidates c2 to c4.

Although the operations S321 to S324 are described by way of example in determining the first candidate c1, the present disclosure is not limited thereto. The memory controller 110 may determine at least one of a plurality of candidates, determine offsets, and perform an operation on the determined at least one candidate and offsets to determine the remaining candidates.

FIG. 8A is a diagram illustrating an offset according to some embodiments of the present disclosure. Referring to FIG. 8A, the vertical axis represents the first result value Y, which is the difference between the first and second mean values a1 and a2, and the horizontal axis represents a second result value X, which is the ratio of the first and second variance values b1 and b2.

Referring to FIGS. 1, 7, 6A to 6D, and 8A, the memory controller 110 determines the second to fourth candidates c2 to c4 from among the candidates (e.g., the first to fourth candidates c1 to c4) based on the first and second mean values a1 and a2 and the first and second variance values b1 and b2 of the adjacent threshold voltage distributions (e.g., the first and second threshold voltage distributions D1 and D2) of the plurality of memory cells MC.

Furthermore, the memory controller 110 may perform comparison operations on the first and second mean values a1 and a2 and the first and second variance values b1 and b2 to determine the first result value Y, which is the difference between the first and second mean values, and the second result value X, which is the ratio of the first and second variance values b1 and b2.

Each of the first result value Y and the second result value X may belong to one of a plurality of first and second discrete ranges R11 to R14 and R21 to R22. For example, the difference value (i.e., the first result value Y) between the first and second mean values a1 and a2 may be between a first difference value y1 and a fourth difference value y4, and these difference values may be divided into the plurality of first discrete ranges R11 to R14. Therefore, the first result value Y may belong to one of the plurality of first discrete ranges R11 to R14.

In addition, for example, the ratio (or a proportional value) of the first and second variance values b1 and b2 (i.e., the second result value X) may be between a first proportional value x1 and a third proportional value x3, and these proportional values may be divided into the plurality of second discrete ranges R21 to R22. Therefore, the second result value X may be divided into the plurality of second discrete ranges R21 to R22.

The memory controller 110 may determine to which of the plurality of first and second discrete ranges R11 to R14 and R21 to R22 the first result value Y and the second result value X belong, respectively, and may determine one of a plurality of offset values O1 to O8 as an offset based on the discrete ranges to which the first result value Y and the second result value X belong, respectively. For example, the memory controller 110 may determine the first offset value O1 as the offset based on determining that the first result value Y belongs to the (1-1)th discrete range R11 and the second result value X belongs to the (2-1)th discrete range R21.

The memory controller 110 may determine the first candidate c1 by performing an addition operation using the determined offset and one of the other candidates (e.g., the second to fourth candidates c2 to c4). The memory controller 110 may reduce the overhead required to determine the first candidate c1 or other candidates through operations using the offset, thereby improving the read performance of the storage device 100.

For better understanding, combinations of the plurality of first and second discrete ranges R11 to R14 and R21 to R22 (e.g., a combination of the (1-1)th discrete range R11 and the (2-1)th discrete range R21 corresponding to the first offset value O1) are all shown as corresponding to offset values (e.g., the first to eighth offset values O1 to O8), but the present disclosure is not limited thereto. In some embodiments, only some combinations among the plurality of first and second discrete ranges R11 to R14 and R21 to R22 may correspond to some of the offset values (e.g., the first to eighth offset values O1 to O8).

For better understanding, the first to fourth difference values y1 to y4, the plurality of first discrete ranges R11 to R14, the first to third proportional values x1 to x3, the plurality of second discrete ranges R21 to R22, and the first to eighth offset values O1 to O8 are described by way of example, but the present disclosure is not limited thereto.

FIG. 8B is a diagram illustrating the offset according to some embodiments of the present disclosure. Referring to FIGS. 1, 7, 6A to 6D, and 8B, the memory controller 110 may include a look-up table LUT (which may be conceptualized as a two-dimensional array or matrix) for determining the offset. The look-up table LUT may store offset values O11 to Onm corresponding to combinations of the first result value Y and the second result value X. For example, offset values may be determined based on horizontal and vertical look up based on the intersection of the first result value Y (e.g., y1 to ym) and the second result value X (e.g., x1 to xn).

The memory controller 110 may determine the second to fourth candidates c2 to c4 from among the candidates (e.g., the first to fourth candidates c1 to c4) based on the first and second mean values a1 and a2 and the first and second variance values b1 and b2 of the adjacent threshold distributions (e.g., the first and second threshold voltage distributions D1 and D2) of the plurality of memory cells MC.

Furthermore, the memory controller 110 may perform comparison operations on the first and second mean values a1 and a2 and the first and second variance values b1 and b2 to determine the first result value Y, which is the difference between the first and second mean values, and the second result value X, which is the ratio of the first and second variance values b1 and b2. In some embodiments, the memory controller 110 may discretize (or quantize) the first result value Y and the second result value X.

The memory controller 110 may load the look-up table LUT and determine an offset based on the discretized or quantized first result value Y and second result value X. For example, the memory controller 110 may determine a (1-1)th offset value O11 as the offset based on determining that the first result value Y is the first difference value y1 and the second result value X is the first proportional value x1.

The memory controller 110 may determine the first candidate c1 by performing an addition operation on the determined offset and one of other candidates (e.g., the second to fourth candidates c2 to c4). The memory controller 110 may reduce the overhead for determining the first candidate c1 or other candidates through the operation using the offset, thereby improving the read performance of the storage device 100.

FIG. 8C is a diagram illustrating the offset according to some embodiments of the present disclosure. Referring to FIG. 8C, the horizontal axis represents a ratio X of the first and second variance values b1 and b2.

Referring to FIGS. 1, 7, 6A to 6D, and 8C, the memory controller 110 determines the second to fourth candidates c2 to c4 among the candidates (e.g., first to fourth candidates c1 to c4) based on the first and second mean threshold voltage values a1 and a2 and the first and second variance values b1 and b2 of the adjacent threshold voltage distributions (e.g., the first and second threshold voltage distributions D1 and D2) of the plurality of memory cells MC.

Furthermore, the memory controller 110 may perform a comparison operation on the first and second variance values b1 and b2 to determine the ratio X of the first and second variance values b1 and b2. The ratio X may belong to one of a plurality of discrete ranges R1 to R3. For example, the ratio (or the proportional value) X of the first and second variance values b1 and b2 may lie between the first proportional value x1 and a fourth proportional value x4, and these proportional values may be divided into the plurality of discrete ranges R1 to R3. Therefore, the ratio X may be divided into the plurality of discrete ranges R1 to R3.

The memory controller 110 may determine to which of the plurality of discrete ranges R1 to R3 the ratio X belongs to. The memory controller 110 may then determine, based on the discrete range to which the ratio X belongs, one of the plurality of offset values O1 to O3 as the offset. For example, the memory controller 110 may determine the first offset value O1 among the plurality of offset values O1 to O4 as the offset based on determining that the ratio X belongs to the first discrete range R1.

The memory controller 110 may determine the first candidate c1 by performing an addition operation on the determined offset and one of other candidates (e.g., the second to fourth candidates c2 to c4). The memory controller 110 may reduce the overhead required to determine the first candidate c1 or other candidates through operations using the offset, thereby improving the read performance of the storage device 100.

For better understanding, the first to fourth proportional value x1 to x4, the plurality of discrete ranges R1 to R3, and the first to fourth offset values O1 to O4 are described by way of example; however, the present disclosure is not limited thereto.

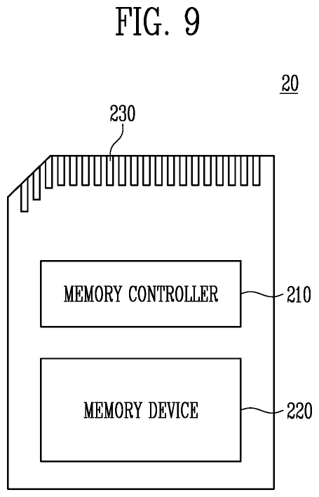

FIG. 9 is a block diagram illustrating a configuration of a memory card system 20 to which a storage device according to some embodiments is applied. Referring to FIG. 9, the memory card system 20 may include a memory controller 210, a memory device 220, and a connector 230.

The memory controller 210 may be coupled to the memory device 220. The memory controller 210 may access the memory device 220. For example, the memory controller 210 may control read, write, erase, and background operations of the memory device 220. The memory controller 210 may be configured to provide an interface between the memory device 220 and the host. The memory controller 210 may be configured to drive firmware for controlling the memory device 220. The memory controller 210 may have the same configuration as the memory controller 110 described above with reference to FIG. 1.

In an embodiment, the memory controller 210 may include components, such as a Random Access Memory (RAM), a processing unit, a host interface, a flash interface, and an ECC circuit.

The memory controller 210 may communicate with an external device through the connector 230. The memory controller 210 may communicate with an external device (e.g., the host) based on a specific communication protocol. In an embodiment, the memory controller 210 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), Wifi, Bluetooth, and non-volatile memory express (NVMe) protocols. In an embodiment, the connector 230 may be defined by at least one of the above-described various communication protocols.

In an embodiment, the memory device 220 may be implemented as any of various non-volatile memory devices, such as Electrically Erasable and Programmable ROM (EEPROM), NAND flash memory, NOR flash memory, Phase-change RAM (PRAM), Resistive RAM (ReRAM), Ferroelectric RAM (FRAM), Spin-Transfer Torque Magnetic RAM (STT-MRAM). The memory device 220 may be configured in the same manner as in the memory device 120 as described above with reference to FIG. 1.

The memory device 220 and the memory controller 210 may be integrated into a single semiconductor device to form a memory card. For example, the memory controller 210 and the memory device 220 may be integrated into a single semiconductor device and form a memory card, such as a personal computer memory card international association (PCMCIA), a compact flash (CF) card, a smart media card (SM or SMC), a memory stick, a multimedia card (MMC, RS-MMC, MMCmicro, or eMMC), a secure digital (SD) card (SD, miniSD, microSD, or SDHC), a universal flash storage (UFS), and the like.

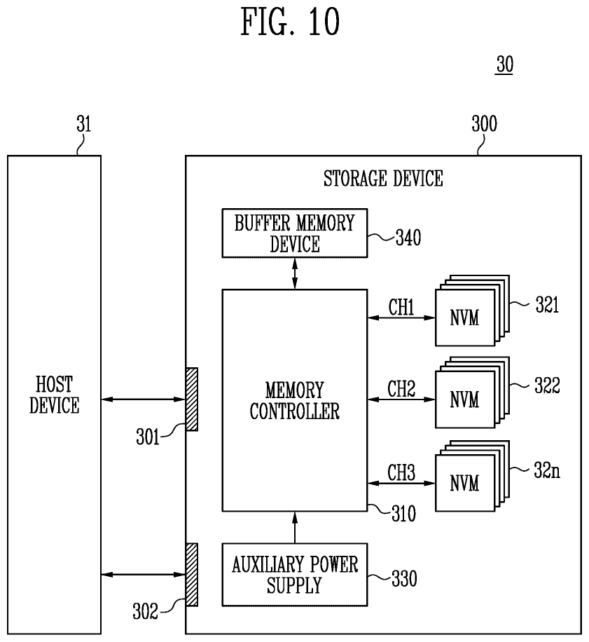

FIG. 10 is a block diagram illustrating a configuration of an electronic system 30 according to some embodiments of the present disclosure. Referring to FIG. 10, the electronic system 30 may include a host device 31 and a storage device 300. The storage device 300 may communicate signals with the host device 31 through a signal connector 301 and may receive power through a power connector 302. The storage device 300 may include a controller 310, a plurality of non-volatile memory devices 321 to 32n, an auxiliary power supply 330, and a buffer memory device 340.

According to an embodiment, the memory controller 310 may perform the functions of the memory controller 110 of FIG. 2.

The controller 310 may control the plurality of non-volatile memory devices 321 to 32n in response to signals received from the host device 31. In an embodiment, the signals may be based on the interfaces of the host device 31 and the storage device 300. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), Wifi, Bluetooth, and non-volatile memory express (NVMe) interfaces.

The auxiliary power supply 330 may be coupled to the host device 31 through the power connector 302. The auxiliary power supply 330 may be supplied and charged with the power from the host device 31. The auxiliary power supply 330 may supply the power of the storage device 300 when the power is not smoothly supplied from the host device 31. For example, the auxiliary power supply 330 may be positioned inside or outside the storage device 300. For example, the auxiliary power supply 330 may be arranged in a main board and supply auxiliary power to the storage device 300.

The buffer memory device 340 may serve as a buffer memory of the storage device 300. For example, the buffer memory device 340 may temporarily store data received from the host device 31 or data received from the plurality of non-volatile memory devices 321 to 32n, or may temporarily store metadata (e.g., mapping tables) of the non-volatile memory devices 321 to 32n. The buffer memory device 340 may include volatile memories such as DRAM, synchronous DRAM (SDRAM), double data rate synchronous dynamic RAM (DDR SDRAM), and low power DDR (LPDDR) SDRAM, or non-volatile memories such as FRAM, ReRAM, STT-MRAM, and PRAM.

According to the present disclosure, a storage device determining a read level and a method of operating the same are provided.

Furthermore, a storage device and an operating method thereof that minimize read fail and improve read performance by determining an optimal read level from among various candidates for read levels are provided.

The embodiments disclosed in the present disclosure are not intended to limit the technical ideas of the present disclosure but rather to illustrate them. The scope of the technical ideas of the present disclosure is not limited by these embodiments. Rather, the scope of protection should be interpreted in accordance with the following claims, and all technical ideas within the scope equivalent thereto should be construed as falling within the present disclosure.

What is claimed is:

1. A method of operating a storage device, the method comprising:
determining, for a plurality of memory cells, a first mean value and a first variance value of a first threshold voltage distribution and a second mean value and a second variance value of a second threshold voltage distribution, the first and second threshold voltage distributions being adjacent to each other;
determining candidates for a read level based on the first and second mean values and the first and second variance values;
performing a first read operation and a first Error Correction Code (ECC) operation on the plurality of memory cells based on a first candidate among the candidates;
performing, in response to a fail of the first ECC operation, a second read operation and a second ECC operation on the plurality of memory cells based on a second candidate among the candidates;
determining, as the read level, a candidate corresponding to a smaller syndrome value of first and second syndrome values respectively indicating numbers of fail bits in the first and second ECC operations; and
performing a third read operation and a third ECC operation on the plurality of memory cells based on the read level.

2. The method of claim 1,
wherein the first and second mean values and the first and second variance values are computed based on first and second Gaussian distributions corresponding to the first and second threshold voltage distributions, respectively, and
wherein the determining the candidates comprises:
determining, as the first candidate, an intersection point of the first and second Gaussian distributions; and
determining, as the second candidate, a mean value of a third distribution corresponding to a result of multiplying the first and second Gaussian distributions.

3. The method of claim 1,
wherein the candidates comprise the first candidate, the second candidate, a third candidate, and a fourth candidate, and
wherein the determining the candidates comprises:
determining the second to fourth candidates; performing comparison operations on the first and second mean values and the first and second variance values, respectively;
determining an offset based on results of the comparison operations; and
determining the first candidate by performing an addition operation between the offset and one of the second to fourth candidates.

4. The method of claim 3, wherein the determining the second to fourth candidate comprises:
determining, as the third candidate, an internal division point of the first and second mean values weighted by the first and second variance values; and
determining, as the fourth candidate, an average of the first and second mean values.

5. The method of claim 3, wherein the determining the offset comprises:
determining first and second discrete ranges to which a first result value corresponding to a difference between the first and second mean values and a second result value corresponding to a ratio of the first and second variance values belong, respectively, based on the results of the comparison operations; and
determining the offset based on the first and second discrete ranges.

6. The method of claim 3, wherein the determining the offset comprises:
determining a first result value corresponding to a difference between the first and second mean values and a second result value corresponding to a ratio of the first and second variance values, based on the results of the comparison operations;
loading a look-up table storing values of the offset; and
determining the offset corresponding to the first result value and the second result value based on the look-up table.

7. The method of claim 3, wherein the determining the offset comprises:
determining a discrete range to which the ratio of the first and second variance values belongs, based on the results of the comparison operations; and
determining the offset based on the discrete range.

8. The method of claim 3,
wherein the performing the second read operation and the second ECC operation further comprises:
performing, in response to a fail of the second ECC operation, a fourth read operation and a fourth ECC operation on the plurality of memory cells based on the third candidate; and
performing, in response to a fail of the fourth ECC operation, a fifth read operation and a fifth ECC operation on the plurality of memory cells based on the fourth candidate0, and
wherein the determining the candidate corresponding to the smaller syndrome value of the first and second syndrome values as the read level comprises determining, as the read level, a candidate corresponding to a smallest syndrome value among a) the first and second syndrome values indicating the numbers of fail bits in the first and second ECC operations and b) third and fourth syndrome values indicating numbers of fail bits in the fourth and fifth ECC operations.

9. The method of claim 1, wherein the determining the candidates comprises:
performing a comparison operation between the first candidate and the second candidate; and
determining the first candidate as the read level in response to determining that the first candidate and the second candidate are identical to each other.

10. The method of claim 1, wherein the performing the first read operation and the first ECC operation comprises determining the first candidate as the read level in response to a pass of the first ECC operation.

11. The method of claim 1, wherein the determining the candidates comprises:
computing values of the candidates based on the first and second mean values and the first and second variance values; and
discretizing the computed values of the candidates to determine the candidates.

12. The method of claim 1,
wherein the first ECC operation and the second ECC operation are hard decoding operations, and
wherein the third ECC operation is a soft decoding operation.

13. A storage device comprising:
a memory device including a plurality of memory cells and a peripheral circuit; and
a memory controller configured to
determine, for the plurality of memory cells, a first mean value and a first variance value of a first threshold voltage distribution and a second mean value and a second variance value of a second threshold voltage distribution, the first and second threshold voltage distributions being adjacent to each other,
determine candidates for a read level based on the first and second mean values and the first and second variance values,
perform a first read operation and a first Error Correction Code (ECC) operation on the plurality of memory cells based on a first candidate among the candidates,
perform, in response to a fail of the first ECC operation, a second read operation and a second ECC operation on the plurality of memory cells based on a second candidate among the candidates,
determine, as the read level, a candidate corresponding to a smaller syndrome value of first and second syndrome values respectively indicating numbers of fail bits in the first and second ECC operations, and
perform a third read operation and a third ECC operation on the plurality of memory cells based on the read level.

14. The storage device of claim 13,
wherein the first and second mean values and the first and second variance values are computed based on first and second Gaussian distributions corresponding to the first and second threshold voltage distributions, respectively, and
wherein the memory controller is configured to:
determine an intersection point of the first and second Gaussian distributions as the first candidate, and
determine a mean value of a third distribution corresponding to a result of multiplying the first and second Gaussian distributions as the second candidate.

15. The storage device of claim 13,
wherein the candidates comprise the first candidate, the second candidate, a third candidate, and a fourth candidate, and
wherein the memory controller is configured to:
perform comparison operations on the first and second mean values and the first and second variance values, respectively,
determine an offset based on results of the comparison operations, and
determine the first candidate by performing an addition operation between the offset and one of the second to fourth candidates.

16. The storage device of claim 15, wherein the memory controller is configured to:
determine an internal division point of the first and second mean values weighted by the first and second variance values as the third candidate; and
determine an average of the first and second mean values as the fourth candidate.

17. The storage device of claim 15, wherein the memory controller is configured to:
determine first and second discrete ranges to which a first result value corresponding to a difference between the first and second mean values and a second result value corresponding to a ratio of the first and second variance values belong, respectively, based on the results of the comparison operations; and
determine the offset based on the first and second discrete ranges.

18. The storage device of claim 15,
wherein the memory controller comprises a look-up table configured to store values of the offset,
wherein the memory controller is configured to:
determine a first result value corresponding to a difference between the first and second mean values and a second result value corresponding to a ratio of the first and second variance values, based on the results of the comparison operations; and
determine the offset corresponding to the first result value and the second result value based on the look-up table.

19. The storage device of claim 15, wherein the memory controller is configured to:
determine a discrete range to which the ratio of the first and second variance values belongs, based on the results of the comparison operations; and
determine the offset based on the discrete range.

20. A method of operating a memory controller, the method comprising:
determining, for a plurality of memory cells, a first mean value and a first variance value of a first threshold voltage distribution and a second mean value and a second variance value of a second threshold voltage distribution, the first and second threshold voltage distributions being adjacent to each other;
determining candidates for a read level based on the first and second mean values and the first and second variance values;
performing a first read operation and a first Error Correction Code (ECC) operation on the plurality of memory cells based on a first candidate among the candidates;
performing, in response to a fail of the first ECC operation, a second read operation and a second ECC operation on the plurality of memory cells based on a second candidate among the candidates;
determining, as the read level, a candidate corresponding to a smaller syndrome value of the first and second syndrome values respectively indicating numbers of fail bits in the first and second ECC operations; and
performing a third read operation and a third ECC operation on the plurality of memory cells based on the read level.
